(19) United States
(12) Patent Application Publication
(10) Pub. No.: US 2017/0077243 A1
(43) Pub. Date: Mar. 16, 2017

(54) SINTERED OXIDE, SPUTTERING TARGET, AND OXIDE SEMICONDUCTOR THIN FILM OBTAINED USING SPUTTERING TARGET

(71) Applicant: SUMITOMO METAL MINING CO., LTD., Tokyo (JP)

(72) Inventors: Tokuyuki NAKAYAMA, Ome-shi (JP); Eiichiro NISHIMURA, Ome-shi (JP); Masashi IWARA, Ome-shi (JP)

(73) Assignee: SUMITOMO METAL MINING CO., LTD., Tokyo (JP)

(21) Appl. No.: 15/125,368

(22) PCT Filed: Mar. 9, 2015
(86) PCT No.: PCT/JP2015/056808

§ 371 Date: Sep. 12, 2016

(30) Foreign Application Priority Data
Mar. 14, 2014 (JP) 2014-052461

(51) Int. Cl. H01L 29/221; C23C 14/34; C04B 35/622; H01L 21/02; C04B 35/01; H01J 37/34; C23C 14/08

(52) U.S. Cl. CPC H01L 29/221; H01J 37/3426; C23C 14/3407; C23C 14/086; H01L 21/02631; H01L 21/02565; H01L 21/02422; H01L 21/02667; C04B 35/01; C04B 35/62218; C04B 2235/3286; C04B 2235/80; C04B 2235/722; C04B 2235/77

(57) ABSTRACT

An oxide sintered body which, when made into an oxide semiconductor thin film by sputtering, can achieve low carrier density and high carrier mobility, and a sputtering target using said oxide sintered body are provided. This oxide sintered body contains indium and gallium as oxides, contains nitrogen, and does not contain zinc. The gallium content in terms of the atomic ratio Ga/(In+Ga) is at least 0.005 but less than 0.20, and substantially no GaN phase is included. Furthermore, the sintered oxide preferably has no Ga₂O₃ phase. A crystalline oxide semiconductor thin film formed using this oxide sintered body as a sputtering target yields a carrier density of 1.0×10¹⁸ cm⁻³ or less, and a carrier mobility of 10 cm²V⁻¹sec⁻¹ or more.

### TECHNICAL FIELD

The present invention relates to an oxide sintered body, a target, and an oxide semiconductor thin film obtained by using the target, and more particularly to a sputtering target that achieves reduced carrier density of a crystalline oxide semiconductor thin film when the sputtering target contains nitrogen, a nitrogen-containing oxide sintered body most suitable for obtaining the sputtering target, and a nitrogen-containing crystalline oxide semiconductor thin film that is obtained by using the sputtering target and has low carrier density and high carrier mobility.

### BACKGROUND ART

Thin film transistors (TFTs) are a type of field effect transistors (hereinafter referred to as FETs). TFTs are three-terminal elements having a gate terminal, a source terminal, and a drain terminal in the basic structure. TFTs are active elements having a function of switching the current between the source terminal and the drain terminal so that a semiconductor thin film deposited on a substrate is used as a channel layer in which electrons or holes move and a voltage is applied to the gate terminal to control the current flowing in the channel layer. TFTs are electronic devices that are most widely used these days in practical application. Typical applications of TFTs include liquid-crystal driving elements.

Currently, most widely used TFTs are metal-insulator-semiconductor-FETs (MIS-FETs) in which a polycrystalline silicon film or an amorphous silicon film is used as a channel layer material. MIS-FETs including silicon are opaque to visible light and thus fail to form transparent circuits. Therefore, when MIS-FETs are used as switching elements for driving liquid crystals in liquid crystal displays, the aperture ratio of a display pixel in the devices is small.

Due to the recent need for high-resolution liquid crystals, switching elements for driving liquid crystals now require high-speed driving. In order to achieve high-speed driving, a semiconductor thin film in which the mobility of electrons or holes, is higher than that in at least amorphous silicon needs to be used as a channel layer.

Under such circumstances, Patent Document 1 proposes a transparent semi-insulating amorphous oxide thin film which is a transparent amorphous oxide thin film deposited by vapor deposition and containing elements of In, Ga, Zn, and O. The composition of the oxide is InGaO₃(ZnO)ₘ (m is a natural number less than 6) when the oxide is crystallized. The transparent semi-insulating amorphous oxide thin film is a semi-insulating thin film having a carrier mobility (also referred to as carrier electron mobility) of more than 1 cm⁻²V⁻¹sec⁻¹ and a carrier density (also referred to as carrier electron density) of 10¹⁶ cm³ or less without doping with an impurity ion. Patent Document 1 also proposes a thin film transistor in which the transparent semi-insulating amorphous oxide thin film is used as a channel layer.

However, as proposed in Patent Document 1, the transparent amorphous oxide thin film (a-IGZO film) containing elements of In, Ga, Zn, and O and deposited by any method of vapor deposition selected from sputtering and pulsed laser deposition has a relatively high electron carrier mobility in a range of from 1 to 10 cm² V⁻¹ sec⁻¹, but instability has been often pointed out as a problem in the case of forming a device such as a TFT as the fact that the amorphous oxide thin film is originally likely to generate oxygen loss and the behavior of the electron carrier is not always stable against external factors such as heat cause adverse effects.

Regarding materials for solving such a problem, Patent Document 2 proposes a thin film transistor including an oxide thin film in which gallium is dissolved in indium oxide. In the oxide thin film, the Ga/(Ga+In) atomic ratio is 0.001 to 0.12, and the percentage of indium and gallium with respect to the total metal atoms is 80 at % or more. The oxide thin film has an In₂O₃ bixbyite structure. An oxide sintered body is proposed as the material of the oxide thin film in which gallium is dissolved in indium oxide. In the oxide sintered body, the Ga/(Ga+In) atomic ratio is 0.001 to 0.12, and the percentage of indium and gallium with respect to the total metal atoms is 80 at % or more. The oxide sintered body has an In₂O₃ bixbyite structure.

However, the carrier density described in Examples 1 to 8 of Patent Document 2 is at the level of 10¹⁸ cm⁻³, and there is still a problem that the carrier density is too high for the oxide semiconductor thin film to be applied to a TFT.

On the other hand, in Patent Documents 3 and 4, a sputtering target composed of an oxide sintered body which further contains nitrogen at a predetermined density in addition to In, Ga, and Zn is disclosed.

However, in Patent Documents 3 and 4, a compact containing indium oxide is sintered in an atmosphere which does not contain oxygen and at a temperature of 1000° C. or higher, and thus indium oxide is decomposed to produce indium. As a result, it is not possible to obtain the desired sintered oxynitride.

Patent Document 1: Japanese Unexamined Patent Application, Publication No. 2010-219538

Patent Document 2: PCT International Publication No. WO2010/032422

Patent Document 3: Japanese Unexamined Patent Application, Publication No. 2012-140706

Patent Document 4: Japanese Unexamined Patent Application, Publication No. 2011-058011

Patent Document 5: Japanese Unexamined Patent Application, Publication No. 2012-253372

### DISCLOSURE OF THE INVENTION

### Problems to be Solved by the Invention

An object of the present invention is to provide a sputtering target which is able to lower the carrier density of a crystalline oxide semiconductor thin film by containing nitrogen but not containing zinc therein, a oxide sintered body which contains nitrogen and is optimum for obtaining the sputtering target, and a crystalline oxide semiconductor thin film which contains nitrogen is obtained by using the oxide sintered body, and has a low carrier density and a high carrier mobility.

### Means for Solving the Problems

The present inventors have performed a trial production of an oxide sintered body in which various elements are added to an oxide of indium and gallium in a trace amount. Furthermore, an experiment was repeated in which the oxide sintered body is machined into a sputtering target, the sputtering target is deposited into a film by sputtering, and the obtained amorphous oxide thin film is subjected to a heat treatment to form a crystalline oxide semiconductor thin film.

In particular, an important result was obtained by further including nitrogen in an oxide sintered body containing indium and gallium as oxides. That is, it was found out that (1) a crystalline oxide semiconductor thin film formed also contains nitrogen, for example, in the case of using the oxide sintered body described above as a sputtering target, which makes it possible to lower the carrier density of the crystalline oxide semiconductor thin film and to increase the carrier mobility thereof, (2) by not including zinc in the oxide sintered body which contains nitrogen, nitrogen is efficiently substitutionally dissolved in the lattice positions of oxygen in the bixbyite structure of the oxide sintered body as well as it is possible to increase the sintering temperature so that the density of sintered body is increased, and (3) by employing ordinary-pressure sintering in an atmosphere having a volume fraction of oxygen over 20%, nitrogen is efficiently substitutionally dissolved in the lattice positions of oxygen in the bixbyite structure of the oxide sintered body dissolved in the lattice positions as well as the density of sintered body of the oxide sintered body is increased.

That is, in a first embodiment of the present invention, an oxide sintered body includes indium and gallium as oxides, in which a gallium content is 0.005 or more and less than 0.20 in terms of Ga/(In+Ga) atomic ratio, the oxide sintered body contains nitrogen but does not contain zinc, and the oxide sintered body does not substantially include a GaN phase having a wurtzite-type structure.

In a second embodiment of the present invention, the gallium content is 0.05 or more and 0.15 or less in terms of Ga/(In+Ga) atomic ratio in the oxide sintered body according to the first embodiment.

In a third embodiment of the present invention, a density of nitrogen is 1×10¹⁹ atoms/cm³ or more in the oxide sintered body according to the first or second embodiment.

In a fourth embodiment of the present invention, the oxide sintered body according to the first to third embodiments is composed only of an In₂O₃ phase having a bixbyite-type structure.

In a fifth embodiment of the present invention, the oxide sintered body according to the first to third embodiments oxide sintered body is composed of an In₂O₃ phase having a bixbyite-type structure, and a GaInO₃ phase having a β-Ga₂O₃-type structure as a formed phase other than the In₂O₃ phase, or a GaInO₃ phase having a β-Ga₂O₃-type structure and a (Ga, In)₂O₃ phase as a formed phase other than the In₂O₃ phase.

In a sixth embodiment of the present invention, an X-ray diffraction peak intensity ratio of the GaInO₃ phase having a β-Ga₂O₃-type structure defined by formula 1 below is in the range of 38% or less in the oxide sintered body according to the fifth embodiment.

100×I[GaInO₃ phase (111)]/{I [In₂O₃ phase (400)]+I [GaInO₃ phase (111)]} [%] Formula 1

In a seventh embodiment of the present invention, the oxide sintered body according to the first to sixth embodiments does not include a Ga₂O₃ phase having a β-G₂O₃-type structure.

In an eighth embodiment of the present invention, the oxide sintered body according to the first to seventh embodiments is sintered by ordinary-pressure sintering in an atmosphere having a volume fraction of oxygen over 20%.

In a ninth embodiment of the present invention, a sputtering target is obtained by machining the oxide sintered body according to the first to eighth embodiments.

In a tenth embodiment of the present invention, a crystalline oxide semiconductor thin film that is obtained by film deposition a substrate by using the sputtering target according to the ninth embodiment by sputtering and then crystallized by a heat treatment in an oxidizing atmosphere.

In an eleventh embodiment of the present invention, a crystalline oxide semiconductor thin film which contains indium and gallium as oxides, contains nitrogen but does not contain zinc and in which a gallium content is 0.005 or more and less than 0.20 in terms of Ga/(In+Ga) atomic ratio, a density of nitrogen is 1×10¹⁸ atoms/cm³ or more, and a carrier mobility is 10 cm² V⁻¹ sec⁻¹ or more.

In a twelfth embodiment of the present invention, a gallium content is 0.05 or more and 0.15 or less in terms of Ga/(In+Ga) atomic ratio in the crystalline oxide semiconductor thin film according to the eleventh embodiment.

In a thirteenth embodiment of the present invention, the crystalline oxide semiconductor thin film according to the eleventh or twelfth embodiment is composed only of an In₂O₃ phase having a bixbyite-type structure.

In a fourteenth embodiment of the present invention, the crystalline oxide semiconductor thin film according to the eleventh or thirteenth embodiment does not include a GaN phase having a wurtzite-type structure.

In a fifteenth embodiment of the present invention, a carrier density is 1.0×10¹⁸ cm⁻³ or less in the crystalline oxide semiconductor thin film according to the eleventh or fourteenth embodiment.

### Effects of the Invention

The oxide sintered body of the present invention which contains indium and gallium as oxides, and contains nitrogen, but does not contain zinc is also able to contain nitrogen in the crystalline oxide semiconductor thin film of the present invention that is obtained by depositing a film by sputtering and then subjecting the film to a heat treatment, for example, when being used as a sputtering target. The crystalline oxide semiconductor thin film has a bixbyite structure and a trivalent nitrogen anion is substitutionally dissolved in the position of negative divalent oxygen, and thus the effect of lowering the carrier density is obtained. Thus, it is possible to increase the on/off ratio of TFTs when applying the crystalline oxide semiconductor thin film of the present invention to TFTs. Therefore, the oxide sintered body, the target, and the oxide semiconductor thin film obtained using the target of the present invention are industrially very useful.

### PREFERRED MODE FOR CARRYING OUT THE INVENTION

An oxide sintered body, a sputtering target, and an oxide thin film obtained using the sputtering target of the present invention will be described below in detail.

The oxide sintered body of the present invention is an oxide sintered body which contains indium and gallium as oxides, and contains nitrogen, but does not contain zinc.

The gallium content, in terms of Ga/(In+Ga) atomic ratio is 0.005 or more and less than 0.20 and preferably 0.05 or more and 0.15 or less. Gallium has an effect of reducing the oxygen loss in the crystalline oxide semiconductor thin film according to the present invention because gallium has a high bonding strength with oxygen. When the gallium content is less than 0.005 in terms of Ga/(In+Ga) atomic ratio this effect is not sufficiently obtained. On the other hand, when the gallium content is 0.20 or more gallium is excessive, and thus it is not possible to obtain a sufficiently high carrier mobility as a crystalline oxide semiconductor thin film.

The oxide sintered body used in the present invention contains nitrogen in addition to indium and gallium in the composition ranges defined above. The density of nitrogen is preferably 1×10¹⁹ atoms/cm³ or more. Nitrogen is not contained in the crystalline oxide semiconductor thin film to be obtained in an amount enough to obtain a carrier density lowering effect when the density of nitrogen in the oxide sintered body is less than 1×10¹⁹ atoms/cm³. Incidentally, the density of nitrogen is preferably measured by dynamic-secondary ion mass spectrometry (D-SIMS).

The oxide sintered body of the present invention does not contain zinc. When containing zinc, the sintering temperature is forced to be lowered since the volatilization of zinc begins before the temperature at which the sintering proceeds is achieved. A decrease in sintering temperature hinders the dissolution of nitrogen in the oxide sintered body as well as makes densification of the oxide sintered body difficult.

### 1. Structure of Oxide Sintered Body

It is preferred that the oxide sintered body of the present invention is composed mainly of an In₂O₃ phase having a bixbyite-type structure. Here, it is preferred that gallium is dissolved in the In₂O₃ phase. Gallium substitutes for indium, which is a trivalent cation, at its lattice positions. It is not preferred that gallium is not dissolved in the In₂O₃ phase but forms a Ga₂O₃ phase having a β-Ga₂O₃-type structure because of unsuccessful sintering or the like. Since the Ga₂O₃ phase has low conductivity, abnormal discharge arises.

It is preferred that nitrogen is substitutionally dissolved in the lattice positions of oxygen, which is a divalent anion, in the In₂O₃ phase taking a bixbyite structure. Incidentally, nitrogen may be present at the interstitial location, grain boundary, or the like in the In₂O₃ phase. As described below, the oxide sintered body is exposed to an oxidizing atmosphere at a temperature of 1300° C. or higher in the sintering process, and thus it is not considered that a great amount of nitrogen can be present at the location described above so that the effect of deteriorating the properties of the oxide sintered body or crystalline oxide semiconductor thin film to be formed of the present invention is a concern.

It is preferred that the oxide sintered body of the present invention is composed mainly of the In₂O₃ phase having a bixbyite-type structure, but it is preferred to include only a GaInO₃ phase having a β-Ga₂O₃-type structure or a GaInO₃ phase having a β-Ga₂O₃-type structure and a (Ga, In)₂O₃ phase in a range in which the X-ray diffraction peak intensity ratio defined by formula 1 below is 38% or less other than the In₂O₃ phase particularly when the gallium content is more than 0.08 in terms of Ga/(In+Ga) atomic ratio.

100×I[GaInO₃ phase (111)]/{I[In₂O₃ phase (400)]+I[GaInO₃ phase (111)]} [%] Formula 1

(wherein I [In₂O₃ phase (400)] represents a (400) peak intensity of the In₂O₃ phase having a bixbyite-type structure, and I [GaInO₃ phase (111)] represents a (111) peak intensity of the complex oxide β-GaInO₃ phase having a β-Ga₂O₃-type structure.)

Incidentally, nitrogen may be contained in the GaInO₃ phase having a β-Ga₂O₃-type structure and the (Ga, In)₂O₃ phase. As described below, it is more preferred to use a gallium nitride powder as a raw material for the oxide sintered body of the present invention, but it is preferred that the oxide sintered body is substantially free of a GaN phase having a wurtzite-type structure in that case. The term “to be substantially free of” means that the weight ratio of the GaN phase having a wurtzite-type structure to the entire formed phases is 5% or less, and the weight ratio is more preferably 3% or less, even more preferably 1% or less, and even more preferably 0%. Incidentally, the weight ratio can be determined by Rietveld analysis through X-ray diffraction measurement. Incidentally, the GaN phase having a wurtzite-type structure is not a problem for the film deposition by direct current sputtering when the weight ratio thereof to the entire formed phases is 5% or less.

### 2. Method for Producing Oxide Sintered Body

The oxide sintered body of the present invention uses an oxide powder consisting of an indium oxide powder and a gallium oxide powder and a nitride powder consisting of a gallium nitride powder and/or an indium nitride powder as raw material powders. Gallium nitride powder is more preferable as the nitride powder since it has a higher temperature at which nitrogen is dissociated than the indium nitride powder.

In the process for producing the oxide sintered body of the present invention, these raw material powders are mixed and then compacted, and the compact is sintered by ordinary-pressure sintering. The formed phases in the structure of the oxide sintered body of the present invention strongly depend on the conditions in each step for producing the oxide sintered body, for example, the particle size of the raw material powders, the mixing conditions, and the sintering conditions.

It is preferred that the structure of the oxide sintered body of the present invention is composed mainly of the In₂O₃ phase having a bixbyite-type structure, because of this, the mean particle size of the raw material powders is preferably 3 μm or less and more preferably 1.5 μm or less. As described above, when the gallium content is 0.08 or more in terms of Ga/(In+Ga) atomic ratio, the oxide sintered body may include, in addition to the In₂O₃ phase, the GaInO₃ phase having a β-Ga₂O₃-type structure or both the GaInO₃ phase having a β-Ga₂O₃-type structure and the (Ga, In)₂O₃ phase. In order to suppress formation of these phases as much as possible, the mean particle size of the raw material powders is preferably 1.5 μm or less.

Indium oxide powder is a raw material for ITO (indium tin oxide), and fine indium oxide powder having good sintering properties has been developed along with improvements in ITO. Since indium oxide powder has been continuously used in large quantities as a raw material for ITO, raw material powder having a mean particle size of 0.8 μm or less is available these days. However, since the amount of gallium oxide powder used is still smaller than that of indium oxide powder used, it is difficult to obtain raw material powder having a mean particle size of 1.5 μm or less for gallium oxide powder. Therefore, when only coarse gallium oxide powder is available, the powder needs to be pulverized into particles having a mean particle size of 1.5 μm or less. It is the same for the gallium nitride powder and/or the indium nitride powder.

The weight ratio of the gallium nitride powder (hereinafter, referred to as the gallium nitride powder weight ratio) to the total amount of the gallium oxide powder and the gallium nitride powder in the raw material powders is preferably 0.60 or less. It is difficult to compact or sinter the oxide sintered body when the weight ratio is more than 0.60, and the density of the oxide sintered body is significantly lowered when the weight ratio is 0.70.

In the process for sintering the oxide sintered body of the present invention, ordinary-pressure sintering is preferably employed. Ordinary-pressure sintering is a simple and industrially advantageous method, and is also an economically preferable means.

When ordinary-pressure sintering is used, a compact is first produced as described above. Raw material powders are placed in a resin pot and mixed with a binder (for example, PVA) and the like by wet ball milling or the like. It is preferred to perform the ball mill mixing for 18 hours or longer in order to suppress the formation of a GaInO₃ phase having a β-G₂O₃-type structure or a GaInO₃ phase having a β-Ga₂O₃-type structure and a (Ga, In)₂O₃ phase other than the In₂O₃ phase when the oxide sintered body of the present invention is composed mainly of the In₂O₃ phase having a bixbyite-type structure and the gallium content is more than 0.08 in terms of Ga/(In+Ga) atomic ratio. At this time, hard ZrO₂ balls may be used as mixing balls. After mixing, the slurry is taken out, filtrated, dried, and granulated. Subsequently, the resultant granulated material is compacted under a pressure of about 9.8 MPa (0.1 ton/cm²) to 294 MPa (3 ton/cm²) by cold isostatic pressing to form a compact.

The sintering process by ordinary-pressure sintering is preferably preformed in an atmosphere containing oxygen. The volume fraction of oxygen in the atmosphere is preferably over 20%. In particular, when the volume fraction of oxygen is over 20%, the oxide sintered body is further densified. An excessive amount of oxygen in the atmosphere causes the surface of the compact to undergo sintering in advance during the early stage of sintering. Subsequently, sintering proceeds while the inside of the compact is reduced, and a highly dense oxide sintered body is finally obtained. In the process in which sintering proceeds in the inside of the compact, the nitrogen which is dissociated from gallium nitride and/or indium nitride of the raw material powder is substitutionally dissolved in the lattice positions of oxygen, which is a divalent anion, in the In₂O₃ phase having a bixbyite-type structure. Incidentally, when a GaInO₃ phase having a β-Ga₂O₃-type structure or a GaInO₃ phase having a β-Ga₂O₃-type structure and a (Ga, In)₂O₃ phase are formed other than the In₂O₃ phase, the nitrogen may be substitutionally dissolved in the lattice positions of oxygen, which is a divalent anion, in these phases.

In an atmosphere free of oxygen, the surface of the compact does not undergo sintering and as a result, densification of the sintered body does not proceed. If oxygen is absent, indium oxide decomposes particularly at about 900° C. to 1000° C. to form metal indium, which makes it difficult to obtain a desired oxide sintered body.

The temperature range of ordinary-pressure sintering is from 1300 to 1550° C., and more preferably sintering is performed at 1350 to 1450° C. in an atmosphere obtained by introducing oxygen gas into air in the sintering furnace. The sintering time is preferably 10 to 30 hours and more preferably 15 to 25 hours.

When the sintering temperature is in the above range, and an oxide powder consisting of an indium oxide powder and a gallium oxide powder and a nitride powder consisting of a gallium nitride powder, an indium nitride powder, or a powder as a mixture of these that are controlled to have a mean particle size of 1.5 μm or less are used as raw material powders, it is possible to obtain a oxide sintered body which contains nitrogen and in which the formation of a GaInO₃ phase having a β-G₂O₃-type structure or a GaInO₃ phase having a β-Ga₂O₃-type structure and a (Ga, In)₂O₃ phase other than the In₂O₃ phase is suppressed as much as possible when the oxide sintered body is composed mainly of the In₂O₃ phase having a bixbyite-type structure and the gallium content is more than 0.08 in terms of Ga/(In+Ga) atomic ratio.

At a sintering temperature lower than 1300° C., the sintering reaction does not proceed well. On the other hand, at a sintering temperature higher than 1550° C., densification does not proceed while a member of the sintering furnace reacts with the oxide sintered body. As a result, a desired oxide sintered body is not obtained. In particular, when the gallium content is more than 0.10 in terms of Ga/(In+Ga) atomic ratio, the sintering temperature is preferably 1450° C. or lower. This is because formation of the (Ga, In)₂O₃ phase may become significant in the temperature region of about 1500° C.

The temperature elevation rate until the sintering temperature is reached is preferably in the range of 0.2 to 5° C./min in order to cause debinding without forming cracks in the sintered body. As long as the temperature elevation rate is this range, the temperature may be increased to the sintering temperature in a combination of different temperature elevation rates as desired. During the temperature elevation process, a particular temperature may be maintained for a certain time in order for debinding and sintering to proceed. After sintering, oxygen introduction is stopped before cooling. The temperature is preferably decreased to 1000° C. at a temperature drop rate in the range of preferably 0.2 to 5° C./min, and particularly 0.2° C./min or more and less than 1° C./min.

### 3. Target

The oxide sintered body of the present invention is used as a thin film forming target, and it is particularly suitable as a sputtering target. For use as a sputtering target, the oxide sintered body is cut into a predetermined size, the surface thereof is further grinded, and the oxide sintered body is bonded to a backing plate to provide a target. The target preferably has a flat shape, but may have a cylindrical shape. When a cylindrical target is used, it is preferred to suppress particle generation due to target rotation.

It is important to densify the oxide sintered body of the present invention in order to use the oxide sintered body as a sputtering target. However, the density of the oxide sintered body decreases as the gallium content increases, and thus the preferred density is different depending on the gallium content. The density is preferably 6.7 g/cm³ or more when the gallium content is 0.005 or more and less than 0.20 in terms of Ga/(In+Ga) atomic ratio. The generation of nodules may be caused at the time of using the oxide sintered body in the film deposition by sputtering in mass production when the density is as low as less than 6.7 g/cm³.

The oxide sintered body of the present invention is also suitable as a target (or also referred to as the tablet) for vapor deposition. It is required to control the density of the oxide sintered body to be lower as compared to the sputtering target in the case of using the oxide sintered body as a target for vapor deposition. Specifically, the density is preferably 3.0 g/cm³ or more and 5.5 g/cm³ or less.

### 4. Oxide Semiconductor Thin Film and Method for Depositing Oxide Semiconductor Thin Film

The crystalline oxide semiconductor thin film of the present invention is obtained as follows: once forming an amorphous oxide thin film on a substrate by sputtering using the sputtering target; and subjecting the amorphous oxide thin film to a heat treatment.

Ordinary sputtering is used in the process for forming the amorphous thin film, but in particular, direct current (DC) sputtering is industrially advantageous because the thermal effects are minimized during film deposition and high-rate deposition is achieved. To form the oxide semiconductor thin film of the present invention by direct current sputtering, a gas mixture of an inert gas and oxygen, particularly argon and oxygen, is preferably used as a sputtering gas. Sputtering is preferably performed in a chamber of a sputtering apparatus at an internal pressure of 0.1 to 1 Pa, particularly 0.2 to 0.8 Pa.

The substrate is typically a glass substrate and is preferably an alkali-free glass substrate. In addition, any resin sheet and resin film that withstands the above process temperature can be used.

In the process for forming the amorphous oxide thin film, presputtering can be performed as follows: for example, after evacuation to 2×10⁴ Pa or less, introducing a gas mixture of argon and oxygen until the gas pressure reaches 0.2 to 0.5 Pa; and generating a direct current plasma by applying direct current power so that the direct current power with respect to the area of the target, namely, the direct current power density, is in the range of about 1 to 4 W/cm². It is preferred that, after this presputtering for 5 to 30 minutes, the substrate position be corrected as desired and then sputtering be performed.

In sputter deposition in the amorphous thin film deposition process, the direct current power applied is increased in order to increase the deposition rate. The oxide sintered body of the present invention is composed mainly of the In₂O₃ phase having a bixbyite-type structure, but there is a case in which a GaInO₃ phase having a β-Ga₂O₃-type structure or a GaInO₃ phase having a β-Ga₂O₃-type structure and a (Ga, In)₂O₃ phase are included in the oxide sintered body other than the In₂O₃ phase particularly when the gallium content is more than 0.08 in terms of Ga/(In+Ga) atomic ratio. When the structure of oxide sintered body is almost occupied by the In₂O₃ phase, it is considered that the GaInO₃ phase having a β-Ga₂O₃-type structure and the (Ga, In)₂O₃ phase become a starting point of nodule growth as the sputtering proceeds. However, the formation of those phases is suppressed as much as possible in the oxide sintered body of the present invention by controlling the particle size of the raw material powders or the sintering conditions, and as a result, those phases are substantially finely dispersed so as not to be the starting point of nodule growth. Therefore, the generation of nodules is suppressed and abnormal discharge, such as arcing, hardly occurs even though the direct current power to be applied is increased. Incidentally, the GaInO₃ phase having a β-Ga₂O₃-type structure and the (Ga, In)₂O₃ phase exhibit conductivity to follow that of the In₂O₃ phase although the extent of conductivity thereof does not reach that of the In₂O₃ phase, and thus these phases themselves never become a cause of abnormal discharge.

The crystalline oxide semiconductor thin film of the present invention is obtained by forming an amorphous thin film and then crystallizing this. As the crystallizing method, for example, there is a method in which an amorphous film is once formed at a low temperature, for example, near room temperature, the oxide thin film is then crystallized by being subjected to a heat treatment at a temperature equal to or higher than the crystallization temperature or a method in which a crystalline oxide thin film is deposited by heating the substrate to a temperature equal to or higher than the crystallization temperature of the oxide thin film. The heating temperature in these two methods is only 700° C. or lower, and the treatment temperature is not significantly different from that of the known semiconductor process described in Patent Document 5, for example.

The composition of indium and gallium in the amorphous thin film and the crystalline oxide semiconductor thin film substantially corresponds to the composition thereof in the oxide sintered body of the present invention. That is, the crystalline oxide semiconductor thin film contains indium and gallium as oxides and further contains nitrogen. The gallium content is 0.005 or more and less than 0.20 and preferably 0.05 or more and 0.15 or less in terms of Ga/(In+Ga) atomic ratio.

The density of nitrogen in the amorphous thin film and the crystalline oxide semiconductor thin film is preferably 1×10¹⁸ atoms/cm³ or more in the same manner as in the oxide sintered body of the present invention.

The crystalline oxide semiconductor thin film of the present invention is preferably composed of only the In₂O₃ phase having a bixbyite structure. In the In₂O₃ phase, gallium is substitutionally dissolved in the lattice positions of indium, which is a trivalent cation, and nitrogen is substitutionally dissolved in the lattice positions of oxygen, which is a divalent anion, in the same manner as in the oxide sintered body. A GaInO₃ phase is likely to be formed as a formed phase other than the In₂O₃ phase, but the formed phase other than the In₂O₃ phase is not preferable since it causes a decrease in carrier mobility. In the oxide semiconductor thin film of the present invention, the carrier density is lowered and the carrier mobility is increased by crystallizing the In₂O₃ phase in which gallium and nitrogen are dissolved. The carrier density is preferably 1.0×10¹⁸ cm⁻³ or less and more preferably 3.0×10¹⁷ cm⁻³ or less. The carrier mobility is preferably 10 cm² V⁻¹ sec⁻¹ or more and more preferably 15 cm² V⁻¹ sec⁻¹ or more.

The crystalline oxide semiconductor thin film of the present invention is subjected to micromachining, which is required in applications such as TFTs by wet etching or dry etching. It is possible to perform micromachining by wet etching using a weak acid after the formation of amorphous film when an amorphous film is once formed at a low temperature, and then the oxide thin film is crystallized by being subjected to a heat treatment at a temperature equal to or higher than the crystallization temperature. Most weak acids can be used, but a weak acid composed mainly of oxalic acid is preferably used. For example, commercial products, such as ITO-06N available from Kanto Chemical Co., Inc., can be used. For example, wet etching or dry etching using a strong acid such as an aqueous solution of ferric chloride can be applied when a crystalline oxide thin film is deposited by heating the substrate to a temperature equal to or higher than the crystallization temperature of the oxide thin film, but dry etching is preferred in consideration of the damage to a TFT in the vicinity.

The oxide sintered body of the present invention is composed of only an In₂O₃ phase having a bixbyite-type structure, by the In₂O₃ phase and a GaInO₃ phase having a β-Ga₂O₃-type structure as a phase other than the In₂O₃ phase, or by the In₂O₃ phase and the GaInO₃ phase having a β-G₂O₃-type structure and a (Ga, In)₂O₃ phase as a phase other than the In₂O₃ phase. The thin film to be formed at a low temperature is an amorphous film even when using any of these sintered bodies as a raw material for film deposition, and thus the thin film is easily machined into a desired shape by wet etching using a weak acid as described above. In this case, the thin film formed at a low temperature is a stable amorphous film since the crystallization temperature thereof is increased up to about 250° C. by the effect of containing nitrogen. However, as in Patent Document 2, microcrystals are generated in the thin film to be formed at a low temperature when the oxide sintered body is composed of only the In₂O₃ phase but does not contain nitrogen. That is, a problem such as the generation of residue is caused in the wet etching process.

Although the thickness of the crystalline oxide semiconductor thin film of the present invention is not limited, the thickness is 10 to 500 nm, preferably 20 to 300 nm, and more preferably 30 to 100 nm. When the thickness is less than 10 nm, unfavorable crystallinity is obtained, and as a result, a high carrier mobility is not achieved. When the film thickness is more than 500 nm, it is disadvantageous in that a problem associated with productivity arises.

In addition, the crystalline oxide semiconductor thin film of the present invention has an average transmittance in the visible region (400 to 800 nm) of preferably 80% or more, more preferably 85% or more, and even more preferably 90% or more. When applying the crystalline oxide semiconductor thin film to a transparent TFT, the light extraction efficiency by a liquid crystal element, an organic EL element, and the like as a transparent display device decreases when the average transmittance is less than 80%.

The crystalline oxide semiconductor thin film of the present invention hardly absorbs light in the visible region but has high transmittance. The a-IGZO film described in Patent Document 1 greatly absorbs light particularly on the short wavelength side of the visible region since it contains zinc. In contrast, the oxide semiconductor thin film of the present invention hardly absorbs light particularly on the short wavelength side of the visible region since it does not contain zinc, and for example, the extinction coefficient thereof at a wavelength of 400 nm is 0.05 or less. Therefore, the oxide semiconductor thin film of the present invention has high transmittance to blue light near a wavelength of 400 nm and increases the color development of a liquid crystal element, an organic EL element, and the like, and thus it is suitable as a material for the channel layer in the TFT of these.

### EXAMPLES

A more detailed description is provided below by way of Examples of the present invention, but the present invention is not limited by these Examples.

### <Evaluation of Oxide Sintered Body>

The composition of the metal elements in the obtained oxide sintered body was determined by ICP emission spectroscopy. In addition, the amount of nitrogen in the sintered body was measured by dynamic-secondary ion mass spectrometry (D-SIMS). The formed phases were identified by a powder method with an X-ray diffractometer (available from Philips) using rejects of the obtained oxide sintered body.

### <Evaluation of Basic Properties of Oxide Thin Film>

The composition of the obtained oxide thin film was determined by ICP emission spectrometry. The thickness of the oxide thin film was determined with a surface profilometer (available from KLA-Tencor Corporation). The deposition rate was calculated from the film thickness and the film deposition time. The carrier density and mobility of the oxide thin film were determined with a Hall-effect measurement apparatus (available from TOYO Corporation). The formed phases in the film were identified by X-ray diffraction measurement.

### Examples 1-17

An indium oxide powder, a gallium oxide powder, and a gallium nitride powder were prepared as raw material powders so that each powder has a mean particle size of 1.5 μm or less. These raw material powders were prepared so as to obtain the Ga/(In+Ga) atomic ratio and the weight ratio of the gallium oxide powder and the gallium nitride powder shown in Table 1. The raw material powders were placed in a resin pot together with water and mixed by wet ball milling. In this case, hard ZrO₂ balls were used and the mixing time was 18 hours. After mixing, slurry was taken out, filtrated, dried, and granulated. The granulated material was compacted by cold isostatic pressing under a pressure of 3 ton/cm².

Next, the compact was sintered as described below. The compact was sintered at a sintering temperature of between 1350 and 1450° C. for 20 hours in an atmosphere obtained by introducing oxygen into air in a sintering furnace at a rate of 5 L/min per 0.1 m³ furnace volume. At this time, the temperature was increased by 1° C./min, oxygen introduction was stopped during cooling after sintering, and the temperature was decreased to 1000° C. by 10° C./min.

The composition of the obtained oxide sintered body was analyzed by ICP emission spectrometry. As a result, it was confirmed that the proportion of the metal elements substantially the same as the composition prepared at the time of mixing raw material powders in all Examples. The amount of nitrogen in the oxide sintered body was from 1.0 to 800×10¹⁹ atoms/cm³ as shown in Table 1.

Next, the phase identification of the oxide sintered body was performed by X-ray diffraction measurement, in Examples 1 to 11, only the diffraction peak attributed to the In₂O₃ phase having a bixbyite-type structure or only the diffraction peaks attributed to the In₂O₃ phase having a bixbyite-type structure and the GaInO₃ phase having a β-Ga₂O₃-type structure and the (Ga, In)₂O₃ phase were confirmed, but the GaN phase having a wurtzite-type structure or the Ga₂O₃ phase having a β-Ga₂O₃-type structure were not confirmed. When the oxide sintered body includes a GaInO₃ phase having a β-Ga₂O₃-type structure, the X-ray diffraction peak intensity ratio of the GaInO₃ phase having a β-Ga₂O₃-type structure defined by formula 1 below is shown in Table 1.

100×I[GaInO₃ phase (111)]/{I[In₂O₃ phase (400)]+I[GaInO₃ phase (111)]} [%] Formula 1

TABLE 1

| | Ga/ | | | Density of | | GaInO₃(111) | | |
|---|---|---|---|---|---|---|---|---|
| | (In + Ga) | GaN/ | Sintering | sintered | Density of | Peak | | |
| | Atomic | (Ga₂O₃ + GaN) | temperature | body | Nitrogen | intensity | GaN | Ga₂O₃ |
| | ratio | Weight ratio | (° C.) | (g/cm³) | (atoms/cm³) | ratio | phase | phase |
| Example 1 | 0.005 | 0.60 | 1450 | 6.75 | 2.3 × 10¹⁹ | — | Absence | Absence |
| Example 2 | 0.01 | 0.20 | 1450 | 6.97 | 1.0 × 10¹⁹ | — | Absence | Absence |
| Example 3 | 0.03 | 0.10 | 1450 | 6.96 | 3.0 × 10¹⁹ | — | Absence | Absence |
| Example 4 | 0.05 | 0.10 | 1400 | 7.01 | 5.1 × 10¹⁹ | — | Absence | Absence |
| Example 5 | 0.05 | 0.05 | 1350 | 6.91 | 2.2 × 10¹⁹ | — | Absence | Absence |
| Example 6 | 0.08 | 0.05 | 1400 | 7.02 | 4.3 × 10¹⁹ | — | Absence | Absence |
| Example 7 | 0.08 | 0.40 | 1400 | 6.82 | 3.8 × 10²⁰ | — | Absence | Absence |
| Example 8 | 0.09 | 0.05 | 1400 | 7.01 | 5.2 × 10¹⁹ | 4 | Absence | Absence |
| Example 9 | 0.10 | 0.02 | 1400 | 7.07 | 6.8 × 10¹⁹ | 11 | Absence | Absence |
| Example 10 | 0.10 | 0.50 | 1400 | 6.81 | 8.0 × 10²¹ | 19 | Absence | Absence |
| Example 11 | 0.12 | 0.02 | 1400 | 6.99 | 7.2 × 10¹⁹ | 16 | Absence | Absence |
| Example 12 | 0.15 | 0.01 | 1400 | 6.95 | 3.3 × 10¹⁹ | 22 | Absence | Absence |
| Example 13 | 0.19 | 0.20 | 1400 | 6.78 | 8.7 × 10¹⁹ | 38 | Absence | Absence |

In addition, the density of the oxide sintered body was measured to obtain a result of from 6.75 to 7.07 g/cm³.

The oxide sintered body was machined to a size of 152 mm in diameter and 5 mm in thickness. The sputtering surface was grinded with a cup grinding wheel so that the maximum height Rz was 3.0 μm or less. The machined oxide sintered body was bonded to an oxygen-free copper backing plate by using metal indium to provide a sputtering target.

Film deposition by direct current sputtering was performed by using the sputtering targets of Examples 1 to 13 and an alkali-free glass substrate (Corning #7059) at room temperature without heating the substrate. The sputtering target was attached to a cathode of a magnetron sputtering apparatus (available from Tokki Corporation) having a direct current power supply with no arcing control function. At this time, the target-substrate (holder) distance was fixed at 60 mm. After evacuation to 2×10⁻⁴ Pa or less, a gas mixture of argon and oxygen was introduced at an appropriate oxygen ratio, which depends on the gallium content in each target. The gas pressure was controlled to 0.6 Pa. A direct current plasma was generated by applying a direct current power of 300 W (1.64 W/cm²). After presputtering for 10 minutes, the substrate was placed directly above the sputtering target, namely, in the stationary opposing position, and an oxide thin film having a thickness of 50 nm was deposited. The composition of the obtained oxide thin film was confirmed to be substantially the same as that of the target. In addition, the oxide thin film was confirmed to be amorphous as a result of the X-ray diffraction measurement. The obtained amorphous oxide thin film was subjected to a heat treatment for 30 minutes at 300 to 475° C. in air. The oxide thin film after the heat treatment was confirmed to be crystallized as a result of the X-ray diffraction measurement, and the main peak thereof was In₂O₃ (222). The Hall effect measurement was performed on the obtained crystalline oxide semiconductor thin film to obtain the carrier density and the carrier mobility. The obtained evaluation results are summarized in Table 2.

TABLE 2

| | Ga/ | Temperature | | Crystal | | | Carrier |
|---|---|---|---|---|---|---|---|
| | (In + Ga) | for heat | Film | structure | Density of | Carrier | mobility |
| | Atomic | treatment | thickness | of thin | Nitrogen | density | (cm²/ |
| | ratio | (° C.) | (nm) | film | (atoms/cm³) | (×10¹⁷ cm⁻³) | V⁻¹ sec⁻¹) |
| Example 1 | 0.005 | 300 | 50 | Bixbyite | 2.7 × 10¹⁸ | 8.8 | 10.2 |
| Example 2 | 0.01 | 300 | 50 | Bixbyite | 1.2 × 10¹⁸ | 5.6 | 12.4 |
| Example 3 | 0.03 | 300 | 50 | Bixbyite | 3.8 × 10¹⁸ | 3.2 | 14.2 |
| Example 4 | 0.05 | 300 | 50 | Bixbyite | 6.2 × 10¹⁸ | 0.98 | 18.1 |
| Example 5 | 0.05 | 300 | 50 | Bixbyite | 3.3 × 10¹⁸ | 1.7 | 21.0 |
| Example 6 | 0.08 | 300 | 50 | Bixbyite | 5.1 × 10¹⁸ | 0.88 | 20.3 |
| Example 7 | 0.08 | 350 | 50 | Bixbyite | 2.9 × 10¹⁹ | 0.77 | 18.3 |
| Example 8 | 0.09 | 300 | 50 | Bixbyite | 6.9 × 10¹⁸ | 0.76 | 20.2 |
| Example 9 | 0.10 | 325 | 50 | Bixbyite | 5.7 × 10¹⁸ | 0.73 | 20.1 |
| Example 10 | 0.10 | 350 | 50 | Bixbyite | 7.8 × 10²⁰ | 0.60 | 18.4 |
| Example 11 | 0.12 | 350 | 50 | Bixbyite | 5.4 × 10¹⁸ | 0.62 | 18.0 |
| Example 12 | 0.15 | 375 | 50 | Bixbyite | 1.1 × 10¹⁸ | 0.69 | 18.0 |
| Example 13 | 0.19 | 475 | 50 | Bixbyite | 4.0 × 10¹⁸ | 0.23 | 13.0 |

### Comparative Example 1

The Ga/(In+Ga) atomic ratio and the weight ratio of the gallium oxide powder and the gallium nitride powder were set to be the same as in Example 3, further zinc oxide was prepared so as to be 0.10 in terms of Zn/(In+Ga+Zn) atomic ratio, and a compact was fabricated by the same method as in Example 3. The obtained compact was sintered under the same conditions as in Example 3.

The obtained oxide sintered body violently reacted with the member for sintering which was made of aluminum oxide and used in the sintering furnace as a result of the volatilization of zinc oxide. In addition, reduced metal zinc was produced and thus the molten trace remained on the sintered body. It was confirmed that densification of the oxide sintered body by sintering has not proceeded by this effect. Because of this, the composition analysis of the metal elements in the oxide sintered body, the measurement of the amount of nitrogen therein, and the measurement of the density thereof were not performed, and sputtering evaluation was not possible to carry out.

### Comparative Example 2-5

The same raw material powders as those in Examples 1 to 13 were prepared so as to have the Ga/(In+Ga) atomic ratio and the weight ratio of the gallium oxide powder and the gallium nitride powder shown in Table 3, and the oxide sintered body was fabricated by the same method as in Examples 1 to 13.

The composition analysis of the obtained oxide sintered body was performed by ICP emission spectroscopy, and it was confirmed in any of the present Comparative Examples that the composition of the metal elements is substantially the same as the composition prepared at the time of mixing the raw material powders. In addition, the amount of nitrogen in the oxide sintered body was from 0.55 to 78×10¹⁹ atoms/cm³ as shown in Table 3.

TABLE 3

| | | GaN/ | | Density | Density | GaInO₃ | | |
|---|---|---|---|---|---|---|---|---|
| | Ga/ | (Ga₂O₃ + | | of | of | (111) | | |
| | (In + Ga) | GaN) | Sintering | sintered | Nitrogen | Peak | | |
| | Atomic | Weight | temperature | body | (atoms/ | intensity | GaN | Ga₂O₃ |
| | ratio | ratio | (° C.) | (g/cm³) | cm³) | ratio | phase | phase |
| Comparative | 0.001 | 0.60 | 1450 | 6.90 | 5.5 × 10¹⁸ | — | Absence | Absence |
| Example 2 | | | | | | | | |
| Comparative | 0.05 | 0.70 | 1400 | 6.04 | 3.5 × 10²⁰ | — | Presence | Absence |
| Example 3 | | | | | | | | |
| Comparative | 0.65 | 0.10 | 1450 | 6.12 | 6.4 × 10²⁰ | 119 | Absence | Absence |
| Example 4 | | | | | | | | |
| Comparative | 0.80 | 0.10 | 1450 | 6.09 | 7.8 × 10²⁰ | — | Absence | Presence |
| Example 5 | | | | | | | | |
| Comparative | 0.10 | 0.02 | 1200 | Not | Not | — | Not | Not |
| Example 6 | | | | measured | measured | | measured | measured |

Next, the phase identification of the oxide sintered body was performed by the X-ray diffraction measurement. In Comparative Example 2, only the diffraction peak attributed to the In₂O₃ phase having a bixbyite-type structure was confirmed. In Comparative Example 3, the diffraction peak attributed to the GaN phase having a wurtzite-type structure was also confirmed in addition to the diffraction peak attributed to the In₂O₃ phase having a bixbyite-type structure, and the weight ratio of the GaN phase to the entire phases by Rietveld analysis was more than 5%. In Comparative Example 4, the diffraction peaks attributed to the In₂O₃ phase having a bixbyite-type structure and the GaInO₃ phase having a β-Ga₂O₃-type structure were confirmed. In Comparative Example 5, the diffraction peaks attributed to the Ga₂O₃ phase having a β-Ga₂O₃-type structure were confirmed. In addition, the density of the oxide sintered body was measured, and it was only 6.04 g/cm³ in Comparative Example 3, which is lower than that in Example 4 having the same gallium content.

A sputtering target was obtained by machining the oxide sintered body in the same manner as in Examples 1 to 13. An oxide thin film having a thickness of 50 nm was deposited on an alkali-free glass substrate (Corning #7059) at room temperature by using the obtained sputtering target under the same sputtering conditions as in Examples 1 to 13. Incidentally, arcing frequently occurred in the thin film forming process in Comparative Example 3.

The obtained composition of the oxide thin film was confirmed to be substantially the same as that of the target. In addition, the oxide thin film was confirmed to be amorphous as a result of the X-ray diffraction measurement. The obtained amorphous oxide thin film was subjected to a heat treatment for 30 minutes at 300 to 500° C. in air. The oxide thin film after the heat treatment was confirmed to be crystallized as a result of the X-ray diffraction measurement, and the main peak thereof was In₂O₃ (222). The Hall effect measurement was performed on the obtained crystalline oxide semiconductor thin film to obtain the carrier density and the carrier mobility. The obtained evaluation results are summarized in Table 4.

TABLE 4

| | Ga/ | Temperature | | Crystal | Density of | Carrier | Carrier |
|---|---|---|---|---|---|---|---|
| | (In + Ga) | for heat | Film | structure | Nitrogen | density | mobility |
| | Atomic | treatment | thickness | of thin | (atoms/ | (×10¹⁷ | (cm²/ |
| | ratio | (° C.) | (nm) | film | cm³) | cm⁻³) | V⁻¹ sec⁻¹) |
| Comparative | 0.001 | 300 | 50 | Bixbyite | 4.2 × 10¹⁷ | 37 | 7.8 |
| Example 2 | | | | | | | |
| Comparative | 0.05 | 300 | 50 | Bixbyite | 5.6 × 10¹⁹ | 13 | 8.2 |
| Example 3 | | | | | | | |
| Comparative | 0.65 | 700 | 50 | Amorphous | 8.3 × 10¹⁹ | 32 | 6.9 |
| Example 4 | | | | | | | |

### Comparative Example 6

The same raw material powders as those in Examples 1 to 17 were prepared so as to have the Ga/(In+Ga) atomic ratio and the weight ratio of the gallium oxide powder and the gallium nitride powder shown in Table 3, and the compact was fabricated by the same method as in Examples 1 to 17. The obtained compact was sintered under the same conditions as in Examples 1 to 13 except that the sintering atmosphere was changed to nitrogen and the sintering temperature was changed to 1200° C.

In the obtained oxide sintered body, it was found that indium oxide is reduced to produce metal indium and the metal indium is volatilized. In addition to that, it was confirmed that the Ga₂O₃ phase having a β-Ga₂O₃-type structure and the GaN phase having a wurtzite-type structure are also present in the oxide sintered body. Incidentally, it was confirmed that the decomposition of indium oxide proceeded and the densification of the oxide sintered body by sintering does not proceed at all when the sintering temperature was further increased while maintaining the nitrogen atmosphere.

Hence, the composition analysis of the metal elements in the oxide sintered body, the measurement of the amount of nitrogen therein, and the measurement of the density thereof were not performed, and the sputtering evaluation was not possible to carry out.

### [Evaluation]

Examples and Comparative Examples of the oxide sintered body of the present invention are compared to each other in Table 1 and Table 3.

In Examples 1 to 13, the oxide sintered bodies are a oxide sintered body which contains indium and gallium as oxides, contains nitrogen, but does not contain zinc, and has the properties of a oxide sintered body so that the gallium content is controlled to 0.005 or more and less than 0.20 in terms of Ga/(In+Ga) atomic ratio. The gallium nitride powder is blended in the oxide sintered body of Examples 1 to 17 so as to have the weight ratio thereof of 0.01 or more and less than 0.20, and as a result, the density of nitrogen in the oxide sintered body is 1×10¹⁹ atoms/cm³ or more. Furthermore, it was found that the obtained sintered body has a high density of sintered body of 6.75 g/cm³ or more in Examples 1 to 13 in which the gallium content is 0.005 or more and less than 0.20 in terms of Ga/(In+Ga) atomic ratio.

From Examples 1 to 7, when the gallium content is from 0.005 to 0.08 in terms of Ga/(In+Ga) atomic ratio, the oxide sintered body is composed only of the In₂O₃ phase having a bixbyite-type structure, it does not substantially include the GaN phase having a wurtzite-type structure, and the Ga₂O₃ phase having a β-Ga₂O₃-type structure is not present in the oxide sintered body. In addition, from Examples 8 to 13, when the gallium content is 0.09 or more and less than 0.20 in terms of Ga/(In+Ga) atomic ratio, the oxide sintered body is composed of the In₂O₃ phase having a bixbyite-type structure and the GaInO₃ phase having a β-G₂O₃-type structure as a formed phase other than the In₂O₃ phase, or the GaInO₃ phase having a β-Ga₂O₃-type structure and the (Ga, In)₂O₃ phase as a formed phase other than the In₂O₃ phase, it does not substantially include the GaN phase having a wurtzite-type structure, and the Ga₂O₃ phase having a β-Ga₂O₃-type structure is not present in the oxide sintered body.

In contrast, in Comparative Example 1, the sintering results of the oxide sintered body which has the same gallium content as that in Example 3 and further contains zinc oxide at 0.10 in terms of Zn/(In+Ga+Zn) atomic ratio, and as a result, when performing the sintering under the completely same conditions as in Example 3, zinc oxide is vigorously volatilized or decomposed to produce metal zinc and thus the desired oxide sintered body of the present invention is not obtained.

In addition, in the oxide sintered body in which the gallium content is 0.001 in terms of Ga/(In+Ga) atomic ratio of Comparative Example 2, the gallium nitride powder is blended in the raw material powders so as to have a weight ratio of 0.60, but the density of nitrogen is less than 1×10¹⁹ atoms/cm³.

Furthermore, in the oxide sintered body in which the gallium content is 0.05 in terms of Ga/(In+Ga) atomic ratio of Comparative Example 3, the gallium nitride powder is blended in the raw material powders so as to have a weight ratio of 0.70, as a result, the density of the sintered body is only 6.04 g/cm³, the oxide sintered body is not composed only of the In₂O₃ phase having a bixbyite-type structure, but it includes the GaN phase having a wurtzite-type structure, which causes arcing in the film deposition by sputtering.

The oxide sintered body in which the gallium content is 0.80 in terms of Ga/(In+Ga) atomic ratio of Comparative Example 5 includes the Ga₂O₃ phase having a β-G₂O₃-type structure, which causes arcing in the film deposition by sputtering other than the In₂O₃ phase having a bixbyite-type structure.

On the other hand, the oxide sintered body in which the gallium content is 0.10 in terms of Ga/(In+Ga) atomic ratio of Comparative Example 6 was sintered in a nitrogen atmosphere without containing oxygen as the sintering atmosphere, as a result, indium oxide is reduced to produce metal indium at a relatively low temperature of 1200° C. and the desired oxide sintered body of the present invention is not obtained.

Next, Examples and Comparative Examples of the oxide semiconductor thin film of the present invention are compared to each other in Table 2 and Table 4.

In Examples 1 to 13, the crystalline oxide semiconductor thin film is a crystalline oxide semiconductor thin film which contains indium and gallium as oxides, contains nitrogen but does not contain zinc, and has the properties of an oxide semiconductor thin film in which the gallium content is controlled to 0.005 or more and less than 0.20 in terms of Ga/(In+Ga) atomic ratio. It was found that the oxide semiconductor thin films of Examples 1 to 13 are all composed only of the In₂O₃ phase having a bixbyite-type structure, and the density of nitrogen therein is 1×10¹⁸ atoms/cm³ or more. In addition, it was found that the carrier density is 1.0×10¹⁸ cm⁻³ or less and the carrier mobility is 10 cm² V⁻¹ sec⁻¹ or more in the oxide semiconductor thin films of Examples 1 to 13. In particular, the oxide semiconductor thin films in which the gallium content is from 0.05 to 0.15 in terms of Ga/(In+Ga) atomic ratio of Examples 4 to 12 exhibit excellent properties, a carrier mobility of 15 cm² V⁻¹ sec⁻¹ or more.

In contrast, the oxide semiconductor thin film in which the gallium content is 0.001 in terms of Ga/(In+Ga) atomic ratio of Comparative Example 2 is composed only of the In₂O₃ phase having a bixbyite-type structure, but the density of nitrogen therein is less than 1×10¹⁸ atoms/cm³ and the carrier mobility does not reach 10 cm² V⁻¹ sec⁻¹.

On the other hand, the oxide semiconductor thin film in which the gallium content is 0.65 in terms of Ga/(In+Ga) atomic ratio of Comparative Example 4 remains amorphous as the In₂O₃ phase having a bixbyite-type structure is not formed even when performing the heat treatment at 700° C., which is the upper limit temperature of the process. Hence, the carrier density therein is more than 1.0×10¹⁸ cm⁻³.

1. An oxide sintered body comprising indium and gallium as oxides, wherein
a gallium content is 0.005 or more and less than 0.20 in terms of Ga/(In+Ga) atomic ratio,
the oxide sintered body contains nitrogen but does not contain zinc, and
the oxide sintered body does not substantially include a GaN phase having a wurtzite-type structure.

2. The oxide sintered body according to claim 1, wherein the gallium content is 0.05 or more and 0.15 or less in terms of Ga/(In+Ga) atomic ratio.

3. The oxide sintered body according to claim 1, wherein a density of nitrogen is 1×10¹⁹ atoms/cm³ or more.

4. The oxide sintered body according to claim 1, wherein the oxide sintered body is composed only of an In₂O₃ phase having a bixbyite-type structure.

5. The oxide sintered body according to claim 1, wherein the oxide sintered body is composed of
an In₂O₃ phase having a bixbyite-type structure,
and a GaInO₃ phase having a β-Ga₂O₃-type structure as a formed phase other than the In₂O₃ phase, or a GaInO₃ phase having a β-Ga₂O₃-type structure and a (Ga, In)₂O₃ phase as a formed phase other than the In₂O₃ phase.

6. The oxide sintered body according to claim 5, wherein an X-ray diffraction peak intensity ratio of a GaInO₃ phase having a β-Ga₂O₃-type structure defined by formula 1 below is in a range of 38% or less.
100×I[GaInO₃ phase (111)]/{I[In₂O₃ phase (400)]+I[GaInO₃ phase (111)]} [%] Formula 1

7. The oxide sintered body according to claim 1, wherein the oxide sintered body does not include a Ga₂O₃ phase having a β-Ga₂O₃-type structure.

8. The oxide sintered body according to claim 1, wherein the oxide sintered body is sintered by ordinary-pressure sintering in an atmosphere having a volume fraction of oxygen over 20%.

9. A sputtering target obtained by machining the oxide sintered body according to claim 1.

10. A crystalline oxide semiconductor thin film obtained by forming an amorphous film on a substrate by using the sputtering target according to claim 9 by sputtering and then crystallizing the amorphous film by a heat treatment in an oxidizing atmosphere.

11. A crystalline oxide semiconductor thin film comprising:
indium and gallium as oxides; and
nitrogen; but
not comprising zinc, wherein
a gallium content is 0.005 or more and less than 0.20 in terms of Ga/(In+Ga) atomic ratio,
a density of nitrogen is 1×10¹⁸ atoms/cm³ or more, and
a carrier mobility is 10 cm² V⁻¹ sec⁻¹ or more.

12. The crystalline oxide semiconductor thin film according to claim 11, wherein the gallium content is 0.05 or more and 0.15 or less in terms of Ga/(In+Ga) atomic ratio.

13. The crystalline oxide semiconductor thin film according to claim 10, wherein the crystalline oxide semiconductor thin film is composed only of an In₂O₃ phase having a bixbyite-type structure.

14. The crystalline oxide semiconductor thin film according to claim 10, wherein the crystalline oxide semiconductor thin film does not include a GaN phase having a wurtzite-type structure.

15. The crystalline oxide semiconductor thin film according to claim 10, wherein a carrier density is 1.0×10¹⁸ cm⁻³ or less.

16. The crystalline oxide semiconductor thin film according to claim 11, wherein the crystalline oxide semiconductor thin film is composed only of an In₂O₃ phase having a bixbyite-type structure.

17. The crystalline oxide semiconductor thin film according to claim 11, wherein the crystalline oxide semiconductor thin film does not include a GaN phase having a wurtzite-type structure.

18. The crystalline oxide semiconductor thin film according to claim 11, wherein a carrier density is 1.0×10¹⁸ cm⁻³ or less.
